(19) United States
(12) Patent Application Publication
(10) Pub. No.: US 2026/0093171 A1
(43) Pub. Date: Apr. 2, 2026

(54) EUV PHOTOMASKS AND MANUFACTURING METHOD THEREOF

(71) Applicant: Taiwan Semiconductor Manufacturing Company, Ltd., Hsinchu (TW)

(72) Inventors: Pei-Cheng HSU, Hsinchu (TW); Ching-Fang YU, Hsinchu (TW); Hsin-Chang LEE, Hsinchu (TW); Sheng-Min WANG, Hsinchu (TW); Ken-Hsien HSIEH, Hsinchu (TW); Sih-Wei CHANG, Hsinchu (TW)

(73) Assignee: Taiwan Semiconductor Manufacturing Company, Ltd., Hsinchu (TW)

(21) Appl. No.: 19/033,044

(22) Filed: Jan. 21, 2025

Related U.S. Application Data
(60) Provisional application No. 63/700,459, filed on Sep. 27, 2024.

(51) Int. Cl. G03F 1/24

(52) U.S. Cl. CPC G03F 1/24

(57) ABSTRACT

A method of manufacturing a photomask includes forming a border layer over a photomask blank. The photomask blank includes: a substrate, a reflective multilayer disposed over the substrate, and an absorber layer disposed over the reflective multilayer. A portion of the border layer is removed to form a recess surrounded by the border layer, and portions of the absorber layer are selectively removed in the recess to form a pattern in the absorber layer. The border layer has a refractive index ranging from 0.87 to 1 and an extinction coefficient greater than or equal to 0.02.

### RELATED APPLICATION

This application claims priority to U.S. Provisional Ser. No. 63/700,459, filed Sep. 27, 2024, the entire content of which is incorporated herein by reference.

### BACKGROUND

Photolithography operations are one of the key operations in the semiconductor manufacturing process. Photolithography techniques include ultraviolet lithography, deep ultraviolet lithography, and extreme ultraviolet lithography (EUVL). The photomask is an important component in photolithography operations. It is critical to fabricate EUV photomasks having a high contrast with a high reflectivity part and a high absorption part.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B show photomask blanks according to embodiments of the present disclosure. FIGS. 1C and 1D show photomasks according to embodiments of the present disclosure. FIGS. 1E and 1F show plan views of photomasks according to embodiments of the present disclosure.

FIGS. 2A and 2B show photomask blanks according to embodiments of the present disclosure.

FIGS. 3A and 3B show photomask blanks according to embodiments of the present disclosure.

FIGS. 4A and 4B show photomask blanks according to embodiments of the present disclosure.

FIGS. 5A, 5B, 5C, 5D, 5E, 5F, 5G, 5H, 5I, 5J, 5K, 5L, 5M, and 5N schematically illustrate a method of manufacturing a photomask according to embodiments of the present disclosure.

FIGS. 6A, 6B, 6C, 6D, 6E, 6F, 6G, 6H, 6I, 6J, 6K, 6L, 6M, and 6N schematically illustrate a method of manufacturing a photomask according to embodiments of the present disclosure.

FIG. 7 illustrates a photomask according to embodiments of the present disclosure.

FIGS. 8A, 8B, 8C, 8D, 8E, 8F, 8G, 8H, 8I, and 8J show various border patterns according to embodiments of the present disclosure.

FIG. 9 shows a flowchart of a method of manufacturing a photomask.

FIG. 10 shows a flowchart of a method of manufacturing a photomask.

FIG. 11 shows a flowchart of a method of manufacturing a semiconductor device.

FIG. 12A shows a flowchart of a method manufacturing a semiconductor device, and FIGS. 12B, 12C, 12D and 12E show a sequential manufacturing operation of a method of making a semiconductor device in accordance with embodiments of present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” In the present disclosure, a phrase “one of A, B and C” means “A, B and/or C” (A, B, C, A and B, A and C, B and C, or A, B and C), and does not mean one element from A, one element from B and one element from C, unless otherwise described. Materials, configurations, processes and/or dimensions as explained with respect to one embodiment may be employed in other embodiments and detailed description thereof may be omitted.

Embodiments of the present disclosure provide methods of manufacturing a photomask. More specifically, the present disclosure provides techniques to prevent or suppress the neighboring die effect.

In EUV photomask blanks, the film stack comprises an absorber layer, a capping layer, a reflective multilayer, a low thermal expansion material (LTEM) substrate, and a backside conductive film. To mitigate the neighboring die effect, a black border may be formed in a peripheral region of the photomask blank by forming a trench in the film stack surrounding the pattern region of photomask blank by removing a portion of the absorber layer, capping layer, and reflective multilayer. However, the etching of most films may introduce a flatness change and defects. Furthermore, two masks are needed to expose the pattern and the black border, and the two layer stitching is a challenge. To address these issues, in embodiments of the disclosure, a border layer is formed over the absorber layer on the extreme ultraviolet (EUV) mask blank. The border layer, absorber layer, capping layer, and reflective multilayer remain in the peripheral region after the EUV mask forming process. The border layer mitigates EUV radiation reflection from the non-patterned areas (border areas or peripheral areas) of the EUV mask onto a substrate being patterned.

EUV lithography (EUVL) employs scanners using light in the extreme ultraviolet (EUV) region, having a wavelength of about 1 nm to about 100 nm, for example, 13.5 nm. The mask is a critical component of an EUVL system. Photomask, mask, and reticle are used interchangeably in this disclosure. Because many optical materials are not transparent to EUV radiation, EUV photomasks are frequently reflective masks. Circuit patterns are formed in an absorber layer disposed over a reflective structure. The absorber layer has a low EUV reflectivity, for example, less than about 3-5%.

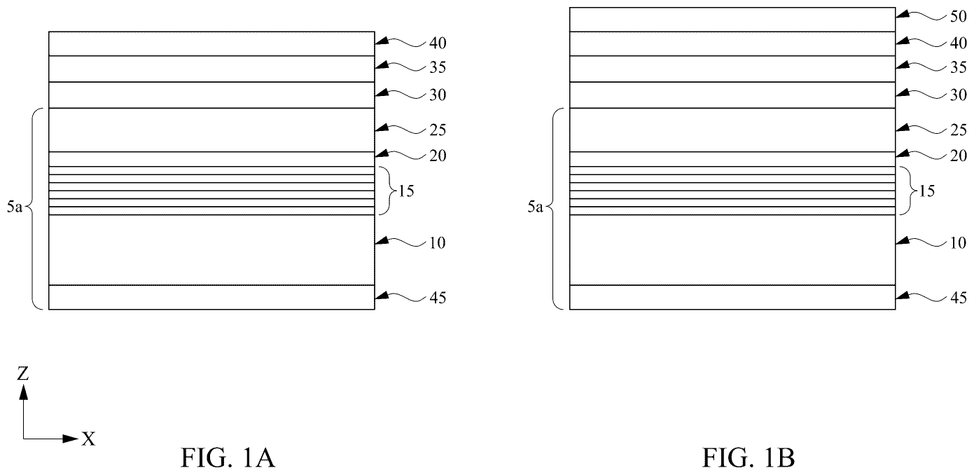

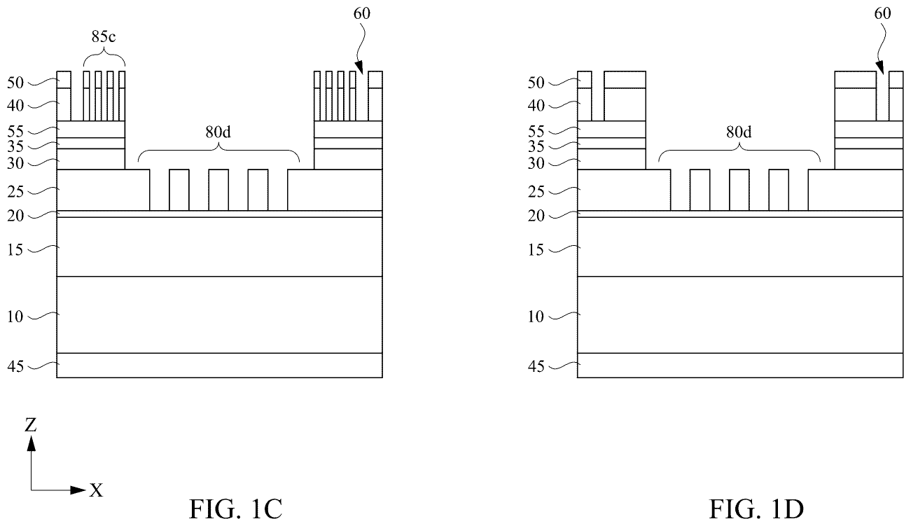

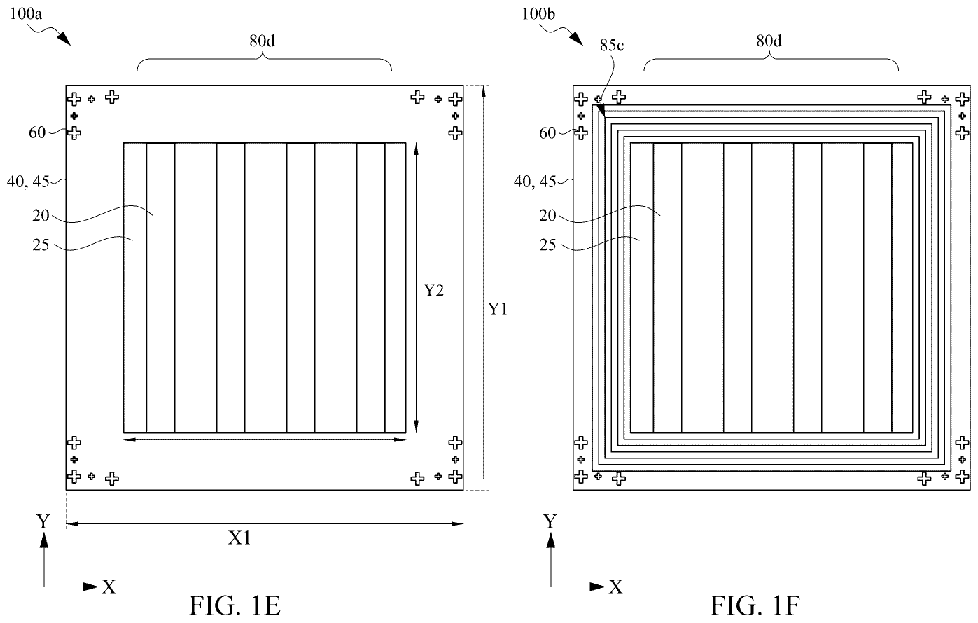

FIGS. 1A and 1B show reflective photomask blank according embodiments of the present disclosure. FIGS. 1C and 1D show cross section views of patterned reflective photomasks ready for use in EUV lithography. FIGS. 1E and 1F are plan views of the photomasks of FIGS. 1C and 1D, respectively.

In some embodiments, the EUV photomask with circuit patterns is formed from a photomask blank 5a. The photo mask blank 5a includes a substrate 10, a reflective multilayer Mo/Si stack 15 of multiple alternating layers of silicon and molybdenum, a capping layer 20, and an absorber layer 25. Further, a backside conductive layer 45 is formed on the backside of the substrate 10, as shown in FIG. 1A and B.

The substrate 10 is formed of a low thermal expansion material in some embodiments. In some embodiments, the substrate is a low thermal expansion glass or quartz, such as fused silica or fused quartz. In some embodiments, the low thermal expansion glass substrate transmits light at visible wavelengths, a portion of the infrared wavelengths near the visible spectrum (near infrared), and a portion of the ultraviolet wavelengths. In some embodiments, the low thermal expansion glass substrate absorbs extreme ultraviolet wavelengths and deep ultraviolet wavelengths near the extreme ultraviolet. In some embodiments, the size X1×Y1 of the substrate 10 is about 152 mm×about 152 mm having a thickness of about 20 mm. In other embodiments, the size of the substrate 10 is smaller than 152 mm×152 mm and equal to or greater than 148 mm×148 mm. The shape of the substrate 10 is square or rectangular in some embodiments.

In some embodiments, the functional layers above the substrate (the multilayer Mo/Si stack 15, the capping layer 20, and the absorber layer 25 have a smaller width than the substrate 10. In other embodiments, the absorber layer 25 has a smaller size in the range from about 138 mm×138 mm to about 142 mm×142 mm than the substrate 10, the multilayer Mo/Si stack 15 and the capping layer 20. The smaller size of one or more of the functional layers can be formed by using a frame shaped cover having an opening in a range from about 138 mm×138 mm to about 142 mm×142 mm, when forming the respective layers by, for example, sputtering. In other embodiments, all of the layers above the substrate 10 have the same size as the substrate 10.

In some embodiments, the Mo/Si multilayer stack 15 includes from about 30 alternating pairs of silicon and molybdenum layers to about 60 alternating pairs of silicon and molybdenum layers. In certain embodiments, from about 40 to about 50 alternating pairs of silicon and molybdenum layers are formed. In some embodiments, the reflectivity is higher than about 70% for the wavelengths of interest e.g., 13.5 nm. In some embodiments, the silicon and molybdenum layers are formed by chemical vapor deposition (CVD), plasma-enhanced CVD (PECVD), atomic layer deposition (ALD), physical vapor deposition (PVD) including sputtering, ion beam deposition (IBD), or any other suitable film forming method. Each layer of silicon and molybdenum is about 2 nm to about 10 nm thick. In some embodiments, the layers of silicon and molybdenum are about the same thickness. In other embodiments, the layers of silicon and molybdenum are different thicknesses. In some embodiments, the thickness of each silicon layer is about 4 nm and the thickness of each molybdenum layer is about 3 nm. In some embodiments, the bottommost layer of the multilayer stack 15 is a Si layer or a Mo layer.

In other embodiments, the multilayer stack 15 includes alternating molybdenum layers and beryllium layers. In some embodiments, the number of layers in the multilayer stack 15 is in a range from about 20 to about 100 although any number of layers is allowed as long as sufficient reflectivity is maintained for imaging the target substrate. In some embodiments, the reflectivity is higher than about 70% for the wavelengths of interest (e.g., 13.5 nm). In some embodiments, the multilayer stack 15 includes about 30 to about 60 alternating layers of Mo and Be. In other embodiments of the present disclosure, the multilayer stack 15 includes about 40 to about 50 alternating layers each of Mo and Be.

The capping layer 20 is disposed over the Mo/Si multilayer stack 15 to prevent oxidation of the multilayer stack 15 in some embodiments. In some embodiments, the capping layer 20 is made of elemental ruthenium (more than 99% Ru, not a Ru compound), a ruthenium alloy (e.g., RuNb, RuZr, RuZrN, RuRh, RuNbN, RuRhN, RuV, RuVN, RuIr, RuTi, RuB, RuP, RuOs, RuPd, RuPt, or RuRe), or a ruthenium based oxide (e.g., RuO₂, RuNbO, RuVO, or RuON), having a thickness of from about 2 nm to about 10 nm. In some embodiments, the capping layer 20 is a ruthenium compound RuₓM₁₋ₓ, where M is at least one of Nb, Ir, Rh, Zr, Ti, B, P, V, Os, Pd, Pt, and Re, and x is more than zero and less than or equal to about 0.5.

In certain embodiments, the thickness of the capping layer 20 is from about 2 nm to about 5 nm. In some embodiments, the capping layer 20 has a thickness of 3.5 nm ±10%. In some embodiments, the capping layer 20 is formed by CVD, PECVD, ALD, PVD, or any other suitable film forming method. In other embodiments, a Si layer is used as the capping layer 20. In some embodiments, one or more layers are disposed between the capping layer 20 and the multilayer 15

In some embodiments, the capping layer 20 includes two or more layers of different materials. In some embodiments, the capping layer 20 includes two or more layers of different Ru based materials. In some embodiments, the capping layer 20 includes two layers having a lower layer and an upper layer, and the upper layer has a higher carbon absorption resistance than the lower layer, and the lower layer has a higher etching resistance during the absorber etching. In certain embodiments, the capping layer 20 includes a RuNb based layer (RuNb or RuNbN) disposed on a RuRh based layer (e.g., RuRh or RuRhN).

The absorber layer 25 is disposed over the capping layer 20. The absorber layer includes a high EUV absorption material having a k value (extinction coefficient) of more than about 0.03 or more than about 0.045. In some embodiments, the absorber layer 25 is Ta based material. In some embodiments, the absorber layer 25 is made of at least one of TaN, TaO, TaB, TaBO, TaBN, TaRu, and TaRuN. In other embodiments, the absorber layer 25 includes a Cr based material, including at least one of CrN, CrBN, CrO, and CrON. In some embodiments, the absorber layer 25 has a multilayered structure of Cr, CrO, or CrON. In some embodiments, the absorber layer is Ir or an Ir based material, including at least one of IrRu, IrPt, IrN, IrAl, IrSi, IrTi, IrRuN, and IrTaON. In some embodiments, the absorber layer is a Ru based material, including at least one of RuPt, RuN, RuW, RuAl, RuSi, RuCr, and RuTi. In some embodiments, the absorber layer is a Pt based material, including at least one of PtIr, PtN, PtAl, PtSi, PtTi, PtRuN. In other embodiments, the absorber layer includes an Os based material, including at least one of OsRu and OsRuN. In other embodiments, the absorber layer is Rh based material, including at least one of RhRu and RhRuN. In other embodiments, the absorber layer is a Hf based material, including at least one of HfRu and HfRuN. In other embodiments, the absorber is a Pd based material, or a Re based material. In some embodiments of the present disclosure, an X based material (where X is any element) means that an amount of X is equal to or more than 50 atomic %.

In other embodiments, the absorber layer material is represented by AₓB_{y}, where A and B are each one or more of Ir, Pt, Ru, Cr, Ta, Os, Pd, Al or Re, and x:y is from about 0.25:1 to about 4:1. In some embodiments, x is different from y (smaller or larger). In some embodiments, the absorber layer further includes one or more of Si, B, or N in an amount of more than zero to about 10 atomic %. In some embodiments, the absorber layer includes about 40 at. % to about 70 at. % of Ru, and from about 2 at. % to about 20 at. % of N.

In some embodiments, the thickness of the absorber layer 25 ranges from about 15 nm to about 100 nm, and ranges from about 20 nm to about 50 nm in other embodiments. In some embodiments, the absorber layer 25 is formed by CVD, PECVD, ALD, PVD, IBD, or any other suitable film-forming method.

At least one hard mask layer is disposed over the absorber layer 25 in some embodiments. A first hard mask layer 30 is disposed over the absorber layer 28 in some embodiments, and in some embodiments a second hard mask layer 35 is disposed over the first hard mask layer 30, as shown in FIGS. 1A and 1B. In some embodiments, the first hard mask layer 30 is made of at least one of TaBN, TaN, MoSi, MoSiN, SiN, SiC, and SiCN and has a thickness of about 2 nm to about 20 nm. In some embodiments, the second hard mask layer 35 is made of at least one of TaBO, Ta₂O₅, TaO₂, TaO, Ta₂O, MoSiO, SiON, SiO₂, and SiCON and has a thickness of about 2 nm to about 20 nm. In some embodiments, the second hard mask layer 35 has a thickness less than the thickness of the first hard mask layer 30. The first hard mask 30 is made of a different material than the absorber layer 25, and the second hard mask layer 35 is made of a different material than the first hard mask layer 30. In some embodiments, the first hard mask layer 30 and the second hard mask layer 35 are formed by CVD, PECVD, ALD, PVD, IBD, or any other suitable film forming method.

At least one border layer is disposed over the at least one hard mask layer in some embodiments. A first border layer 40 is disposed over the at least one hard mask layer 30, 35 and absorber layer 28 in some embodiments, and in some embodiments a second border layer 50 is disposed over the first border layer, as shown in FIGS. 1A and 1B. In some embodiments, the border layers are made of materials having an EUV index of refraction n of about 0.87 to about 1 and EUV extinction coefficient k of greater than or equal to about 0.02. In some embodiments, the border layers are made of at least one selected from the group consisting of Rh, Pd, Ir, Pt, Co, Ni, Te, Cr, W, Hf, Ta, and alloys including PtRu, PtIr, PtRh, PtPd, PtNi, PtCo, PtTa, PtCr, PtTi, IrTa, IrCr, IrW, IrTe, IrNi, IrCo, CrN, NiCo, RhCo, RhNi, RhCr, RhW, and RhTa. In some embodiments, the border layer material may be doped with nitrogen, boron, oxygen, or oxynitride. The first border layer 40 and the second border layer 50 are made of different materials. The microstructure of one or more of the first and second border layers may be polycrystalline having a grain size of about 1 nm to about 5 nm or amorphous. In some embodiments, the border layer 40, 50 are formed by CVD, PECVD, ALD, PVD, IBD, or any other suitable film forming method. In some embodiments, the photomask blank 5a includes three or more border layers. In some embodiments, the first border layer 40 has a thickness ranging from about 10 nm to about 25 nm, and the second border layer 50 has a thickness ranging from about 2 nm to about 25 nm. In other embodiments, the first border layer 40 has a thickness ranging from about 12 nm to about 20 nm, and the second border layer 50 has a thickness ranging from 4 nm to about 20 nm. In some embodiments, the first border layer 40 has a greater thickness than the second border layer 50. In other embodiments, the second border layer 50 has a greater thickness than the first border layer 40.

In some embodiments, the total thickness of the layers disposed over the capping layer 20 (e.g.—absorber layer, hard mask layers, and border layers) is less than the total thickness of the reflective multilayer 15, the capping layer 20, and the absorber layer 25. In some embodiments, the total thickness of the layers disposed over the capping layer ranges from about 30 nm to about 90 nm, but the present disclosure is not limited thereto.

In some embodiments, the backside conductive layer 45 is disposed on a second main surface of the substrate 10 opposing the first main surface of the substrate 10 on which the Mo/Si reflective multilayer stack 15 is formed. In some embodiments, the backside conductive layer 45 is made of TaB (tantalum boride) or other Ta based conductive material. In some embodiments, the tantalum boride is crystalline. The crystalline tantalum boride includes TaB, Ta₅B₆, Ta₃B₄, and TaB₂. In other embodiments, the tantalum boride is polycrystalline or amorphous. In other embodiments, the backside conductive layer 45 is made of a Cr based conductive material (CrN or CrON). In some embodiments, the sheet resistance of the backside conductive layer 45 is equal to or smaller than 20 Ω/□. In certain embodiments, the sheet resistance of the backside conductive layer 45 is equal to or more than 0.1 Ω/□. In some embodiments, the surface roughness Ra of the backside conductive layer 45 is equal to or smaller than 0.25 nm. In certain embodiments, the surface roughness Ra of the backside conductive layer 45 is equal to or more than 0.05 nm. Further, in some embodiments, the flatness of the backside conductive layer 45 is equal to or less than 50 nm. In some embodiments, the flatness of the backside conductive layer 45 is more than 1 nm. A thickness of the backside conductive layer 45 is in a range from about 50 nm to about 400 nm in some embodiments. In other embodiments, the backside conductive layer 45 has a thickness of about 50 nm to about 100 nm. In certain embodiments, the thickness is in a range from about 65 nm to about 75 nm. In some embodiments, the backside conductive layer 45 is formed by atmospheric pressure CVD, low pressure CVD, PECVD, laser-enhanced CVD, ALD, molecular beam epitaxy (MBE), physical vapor deposition including thermal deposition, pulsed laser deposition, electron-beam evaporation, ion beam assisted evaporation and sputtering, or any other suitable film forming method. In cases where CVD is used, source gases include TaCl₅ and BCl₃ in some embodiments.

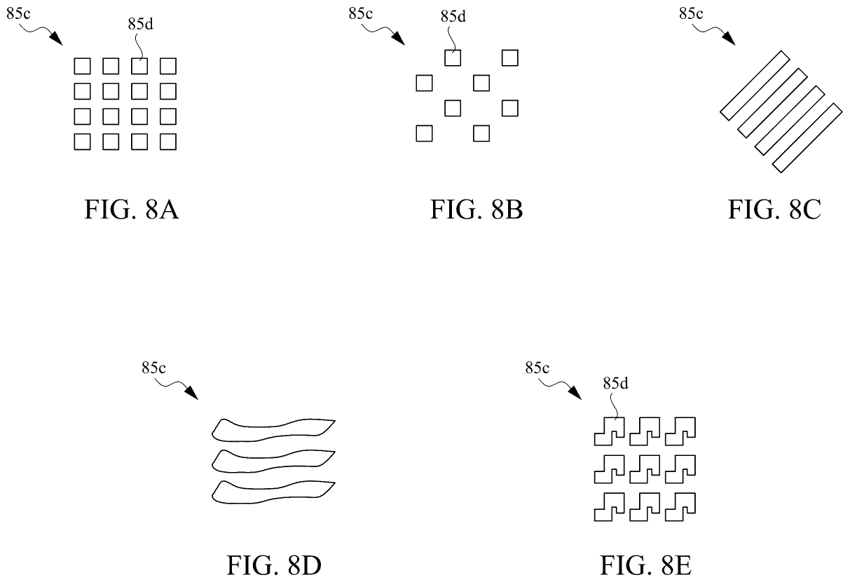

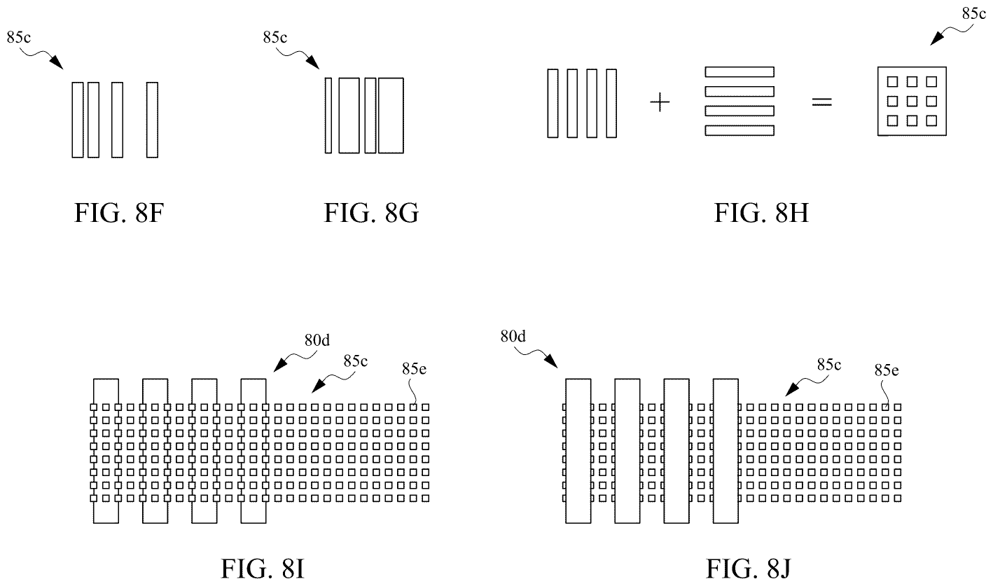

The photomask blanks 5a including the at least one border layer 40, 50 and at least one hard mask 30, 35 are subsequently patterned to form photomasks 100a, 100b, as shown in FIGS. 1C-1F. FIGS. 1C and 1D are cross sectional views and FIGS. 1E and 1F are plan views of the photomasks 100a, 100b. As shown in FIGS. 1C-1F, a mask pattern 80d is formed. The mask pattern 80d corresponds to a circuit pattern to be formed over a substrate to be patterned using the mask 100a, 100b during subsequent processing. As shown in FIGS. 1E and 1F, the border layer 40, 50 surrounds the mask pattern 80d in plan view. At least one alignment mark 60 is formed in the outer portion of the border layer 40, 50 in some embodiments. In some embodiments, the alignment marks 60 are formed at the corners of the photomasks 100a, 100b. As shown in FIGS. 1C and 1F, the border layer 40, 50 surrounding the mask pattern 80d is patterned. As shown in FIG. 1C, the border pattern 85c includes alternating trenches and projections in some embodiments. The border pattern 85c according to embodiments of this disclosure is not limited to the alternating trenches and projections shown in FIG. 1C (see FIGS. 8A-8J). When the width of the projection or the pitch of the border pattern is small enough, destructive interference can be increased to reduce the reflected light.

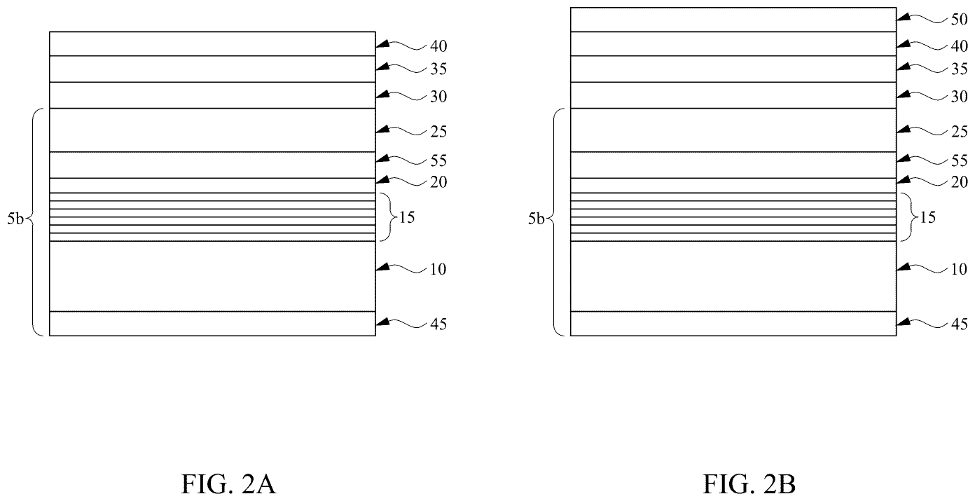

In some embodiments, the photomask blank 5b includes a buffer layer 55 between the capping layer 20 and the absorber layer 25, as shown in FIGS. 2A and 2B. FIG. 2A shows the embodiment having one border layer 40 and FIG. 2B shows the embodiment having two border layers 40, 50. In some embodiments, the buffer layer is made of at least one of TaBN, TaN, MoSi, MoSiN, SiN, SiC, SiCN, CrN, CrON, and RuCr and has a thickness ranging from about 2 nm to about 20 nm. In some embodiments, the buffer layer 55 is formed by CVD, PECVD, ALD, PVD, IBD, or any other suitable film forming method.

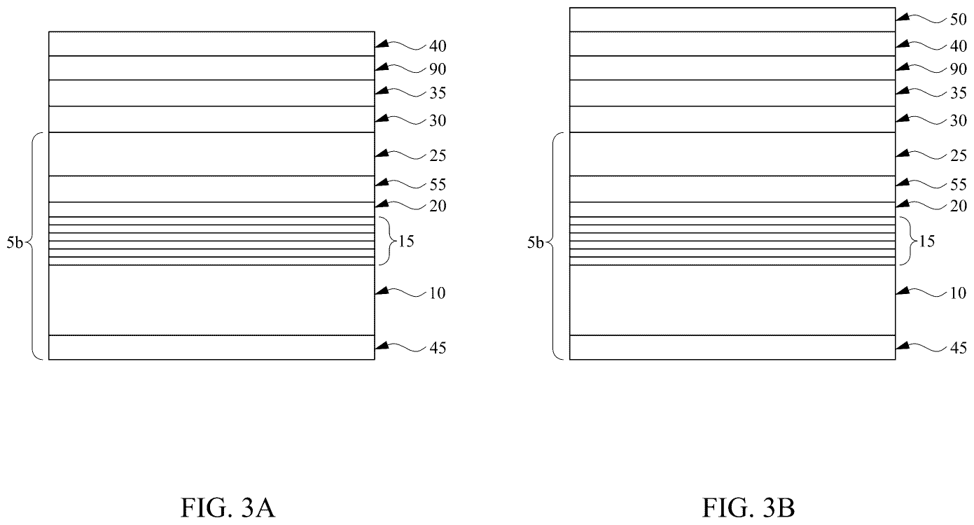

In some embodiments, a third hard mask layer 90 is formed between the second hard mask layer 35 and the first border layer 40, as shown in FIGS. 3A and 3B. In the illustrated embodiment, the mask blank 5b includes the buffer layer 55 between the capping layer 20 and the absorber layer 25. In other embodiments, the third hard mask layer 90 is formed over mask blanks 5a that do not include the buffer layer. FIG. 3A shows the embodiment having one border layer 40 and FIG. 3B shows the embodiment having two border layers 40, 50. In some embodiments, the third hard mask layer 90 is made of at least one of GaN, CrON, CrCON, SiO, SiCO, Y₂O₃, SiCO, and SiCON and has a thickness of about 2 nm to about 20 nm. In some embodiments, the third mask layer 90 is made of a different material than the second hard mask layer 35 and the first border layer. In some embodiments, the third hard mask layer 90 is formed by CVD, PECVD, ALD, PVD, IBD, or any other suitable film forming method.

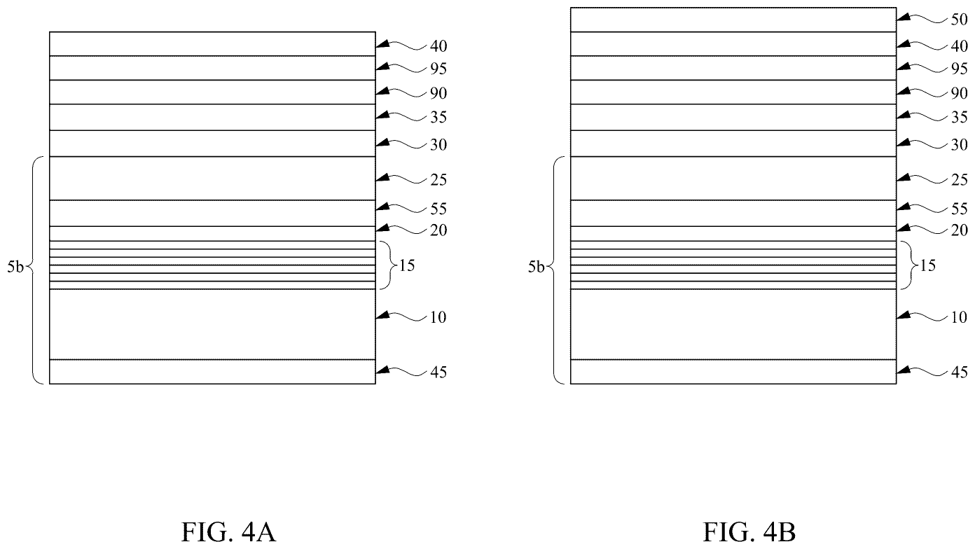

In some embodiments, a fourth hard mask layer 95 is formed between the absorber layer 25 and the first hard mask layer 30, as shown in FIGS. 4A and 4B. In the illustrated embodiment, the mask blank 5b includes the buffer layer 55 between the capping layer 20 and the absorber layer 25. In other embodiments, the fourth hard mask layer 90 is formed over mask blanks 5a that do not include the buffer layer. FIG. 4A shows the embodiment having one border layer 40 and FIG. 4B shows the embodiment having two border layers 40, 50. In some embodiments, the fourth hard mask layer 95 is made of at least one of CrN, CrON, or RuCr and has a thickness of about 2 nm to about 20 nm. In some embodiments, the fourth mask layer 95 is made of a different material than the first hard mask layer 30 and the absorber layer 25. In some embodiments, the fourth hard mask layer 95 is formed by CVD, PECVD, ALD, PVD, IBD, or any other suitable film forming method.

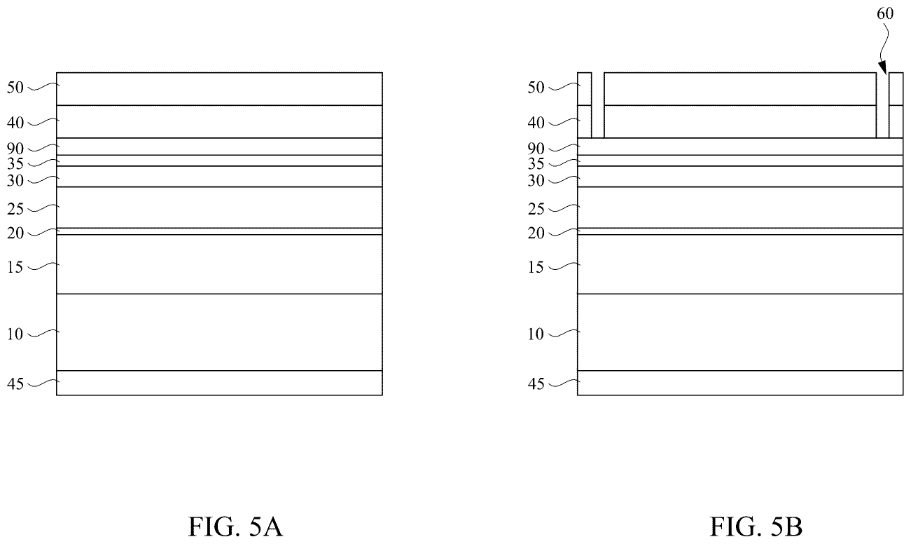

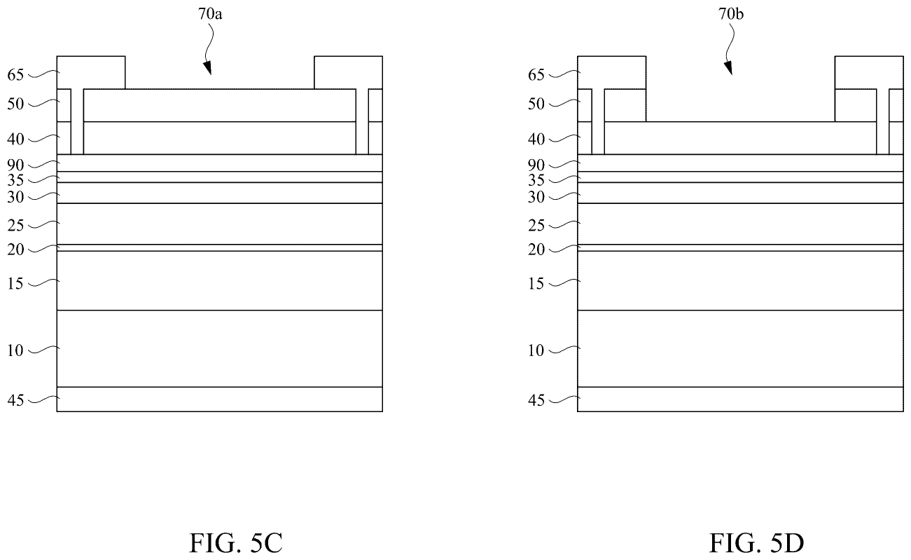

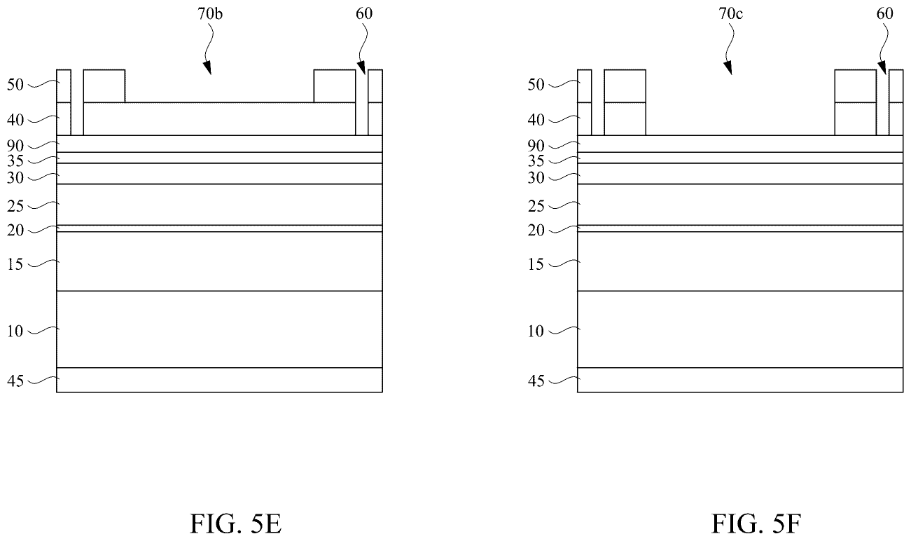

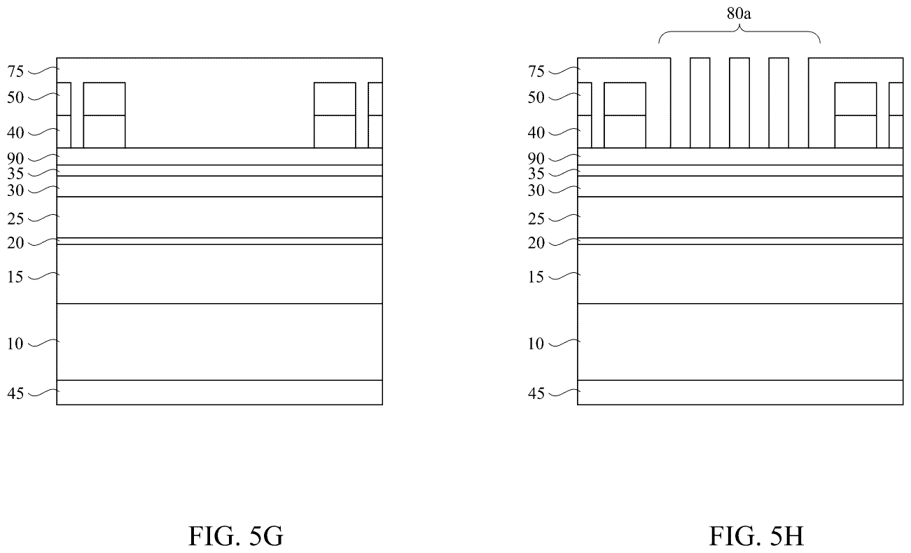

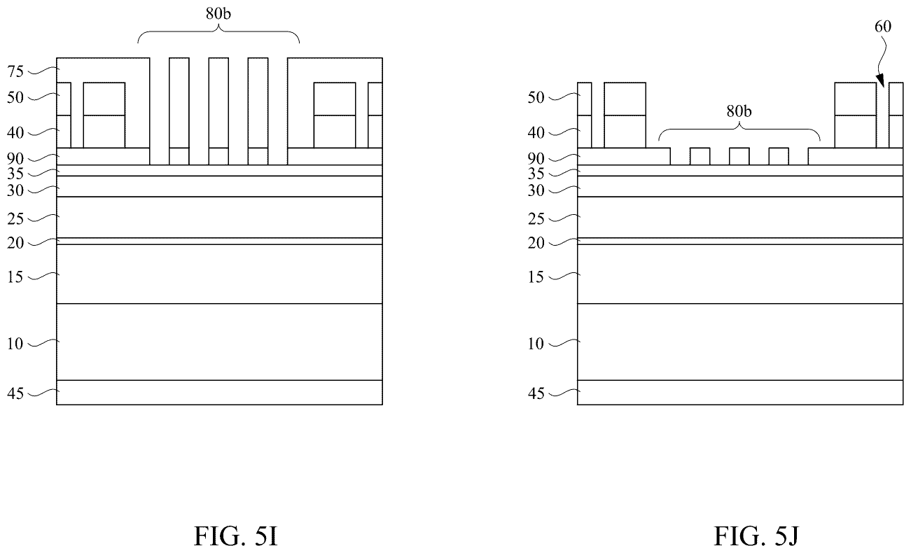

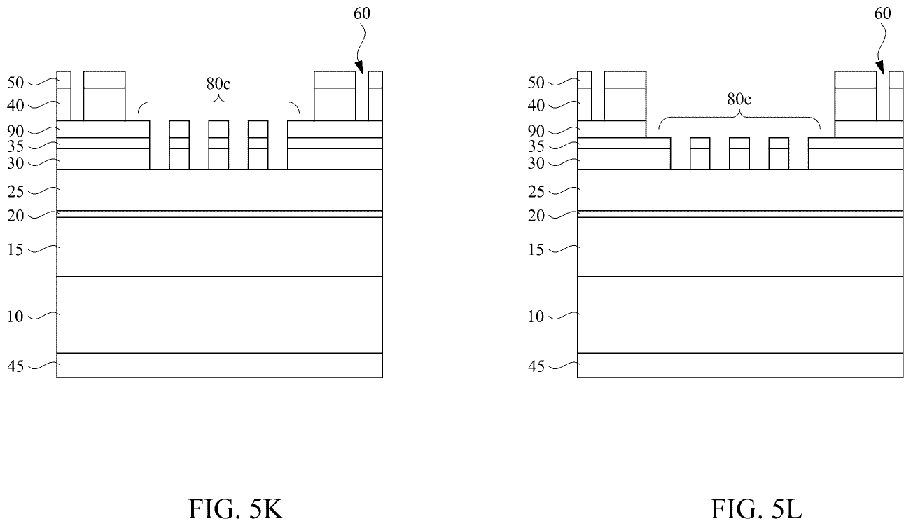

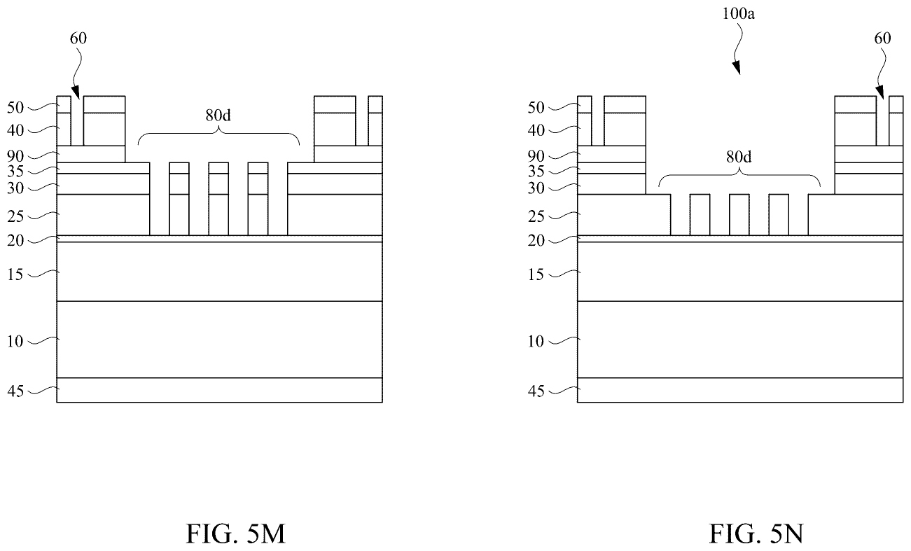

FIGS. 5A-5N schematically illustrate a method of manufacturing a photomask according to embodiments of the present disclosure. Materials, configurations, processes and/or dimensions as explained with respect to the foregoing embodiments may be employed in the following embodiments and detailed description thereof may be omitted. In the illustrated embodiments of FIGS. 5A-5N, the photomask includes two border layers 40, 50 and three hard mask layers 30, 35, 90 while in other embodiments, the photomask includes one or more than two border layers and one or more than three hard mask layers. Although a buffer layer is not shown in FIGS. 5A-5N, in other embodiments, the operations illustrated in FIGS. 5A-5N are performed on photomask blanks including a buffer layer.

A photomask blank is provided having at least one hard mask layer 30, 35 and at least one border layer 40, 50 disposed thereon according to any of the embodiments disclosed herein, as shown in FIG. 5A. In an embodiment, the photomask blank includes an absorber layer 25 made of CrN, with a first hard mask layer 30 made of TaBN, a second hard mask layer 35 made of TaBO, a third hard mask layer 90 made of CrON, a first border layer 40 made of Pt, and a second border layer 50 made of CrN disposed thereon, although the structure is not limited to these materials. An alignment mark 60 is formed in a peripheral region of the border layer 40, 50 in some embodiments, as shown in FIG. 5B. The alignment 60 is configured to align the photomask in subsequent processing operations. The alignment mark 60 is formed using suitable photolithographic and etching operations in some embodiments. The alignment mark may be formed around the periphery of the structure, or may be formed on one or more sides of the structure. In some embodiments, the alignment mark 60 is formed in the first and second border layers 40, 50 exposing a portion of the third hard mask layer 90.

A first photoresist layer 65 is formed over the structure of FIG. 5B, and the photoresist layer 65 is subsequently selectively exposed to actinic radiation and developed to form an opening 70a exposing a portion of the second border layer 50, as shown in FIG. 5C. In some embodiments, the photoresist layer 65 undergoes a post-exposure bake before the development operation. The exposed portion of the second border layer corresponds to the mask pattern region in the subsequently formed photomask. In some embodiments, the photoresist layer 65 is made of a chemically amplified resist or an organometallic resist, and the actinic radiation is deep ultraviolet radiation, extreme ultraviolet radiation, or an electron beam.

Using the remaining photoresist layer 65 as a mask, the second border layer is removed by a suitable etching operation, thereby exposing the first border layer 40 through extended opening 70b, as shown in FIG. 5D. Then, the first photoresist layer is removed by a suitable photoresist removal operation, such as a photoresist stripping or a plasma ashing operation, as shown in FIG. 5E.

In FIG. 5F, the exposed first border layer 40 in the opening 70b is then removed by a suitable etching operation, thereby exposing portions of the third hard mask layer 90 through extended opening 70c. A second photoresist layer 75 is subsequently formed over the structure of FIG. 5F, as shown in FIG. 5G. The second photoresist layer 75 may be formed of the same material as the first photoresist layer 65 or may be formed of a different suitable photoresist.

The second photoresist layer 75 is subsequently selectively exposed to actinic radiation and developed to form a second pattern 80a exposing a portion of the uppermost hard mask layer. In some embodiments, the second photoresist layer 75 undergoes a post-exposure bake before the development operation. In this embodiment, portions of the third hard mask layer 90 are exposed by the second pattern 80a, as shown in FIG. 5H.

Using the second pattern 80a as a mask, the third hard mask layer 90 is etched to form a pattern 80b in the third hard mask layer 90 using a suitable etchant, as shown in FIG. 5I. In some embodiments, the etching operation is a dry etching operation. In some embodiments, the etching is anisotropic etching. The pattern 80b in the third hard mask layer 90 is an extension of the second pattern 80a in the second photoresist layer 75. The remaining photoresist layer is subsequently removed by a suitable photoresist removal operation, such as a photoresist stripping or a plasma ashing operation, as shown in FIG. 5J.

Then, using suitable etchants selective to the second hard mask layer 35 and first hard mask layer 30, the pattern 80b in the third hard mask layer 90 is extended into the second and third hard mask layers 35, 30 forming a pattern 80c in the second and first hard mask layers 35, 30, as shown in FIG. 5K. The etching operation is a dry anisotropic etch in some embodiments. Then, a remaining portion of the third hard mask layer 90 in the opening 70c is removed using a suitable etchant selective to the third hard mask layer, as shown in FIG. 5L. In some embodiments, a portion of the second border layer 50 is removed while etching the third hard mask layer 90.

Using suitable etchants selective to the absorber layer 25, a pattern 80d is formed in the absorber layer 25, as shown in FIG. 5M. The pattern 80d in the absorber layer 25 corresponds to the pattern 80c formed in the first and second hard mask layers 30, 35. A patterned photomask 100a is formed in FIG. 5N by removing the portions of the first and second hard mask layers 30, 35 remaining in the opening 70c. The border layers 40, 50 extend above and surround the absorber layer pattern 80d. The first and second hard mask layers 30, 35 are removed using suitable etchants selective to the first and second hard mask layers. In some embodiments, the etchant is a dry anisotropic etch.

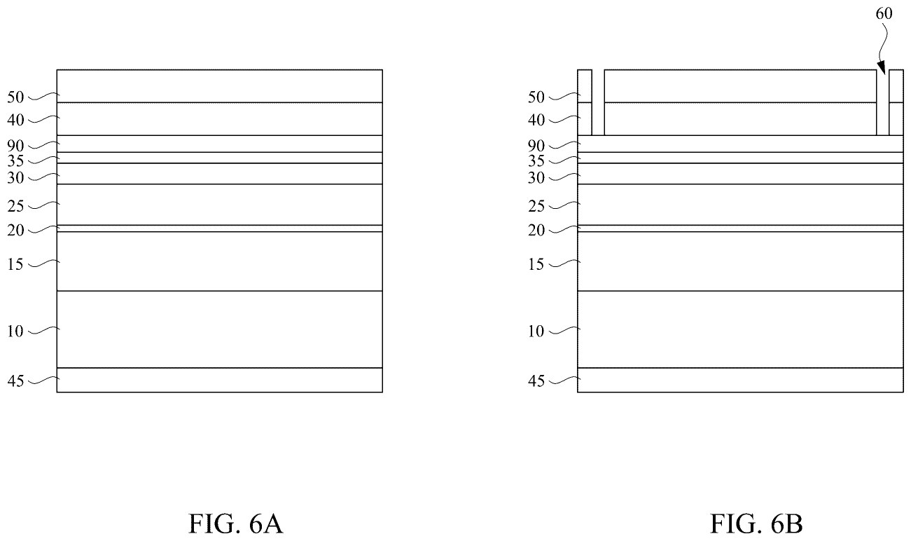

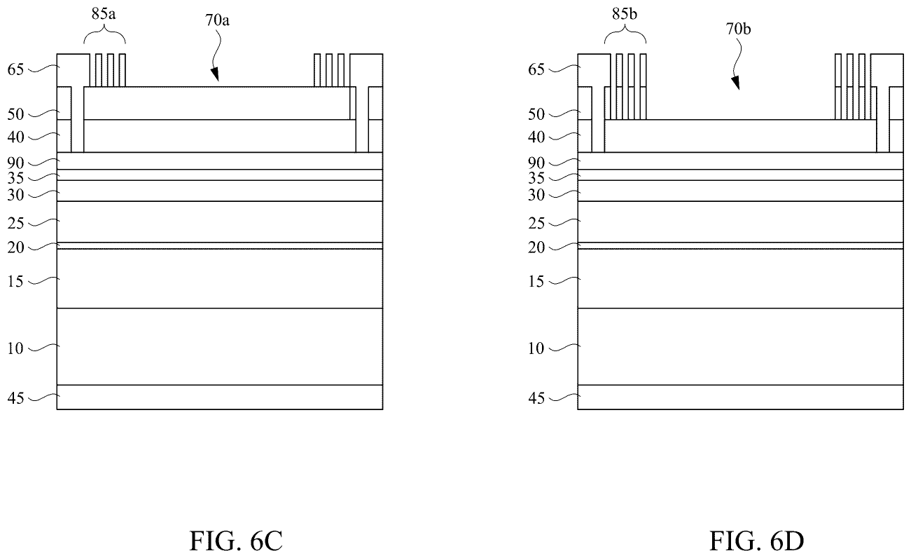

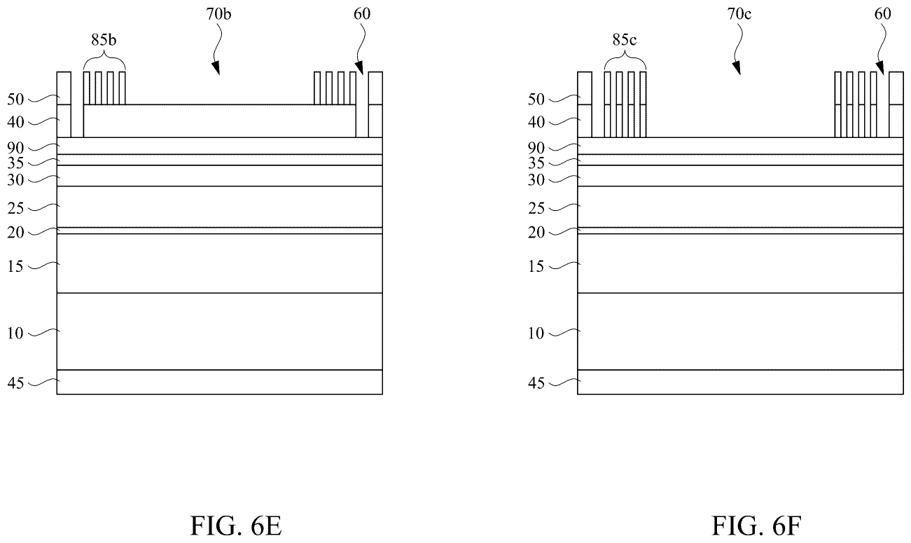

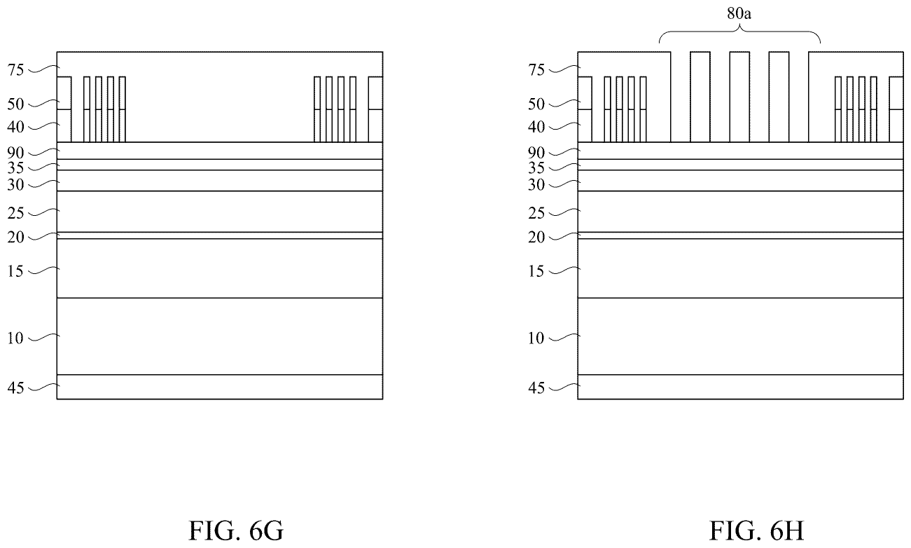

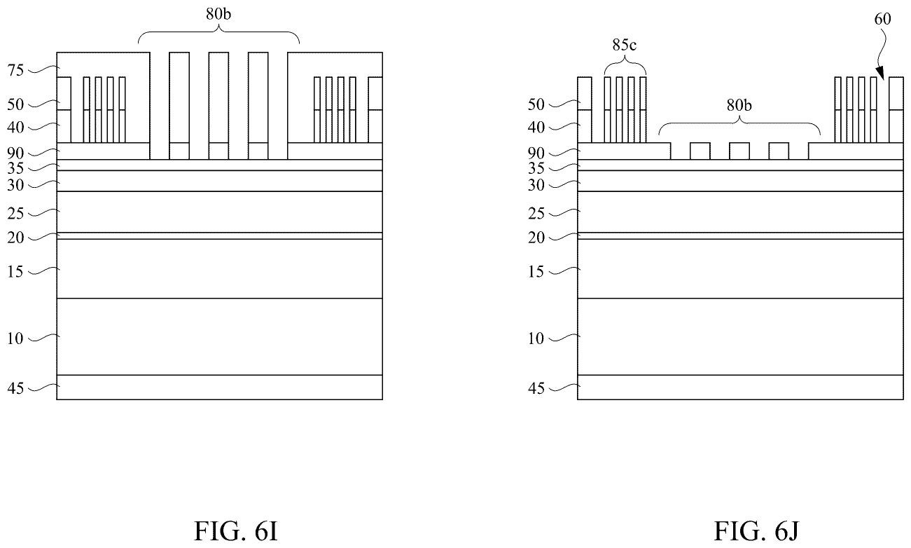

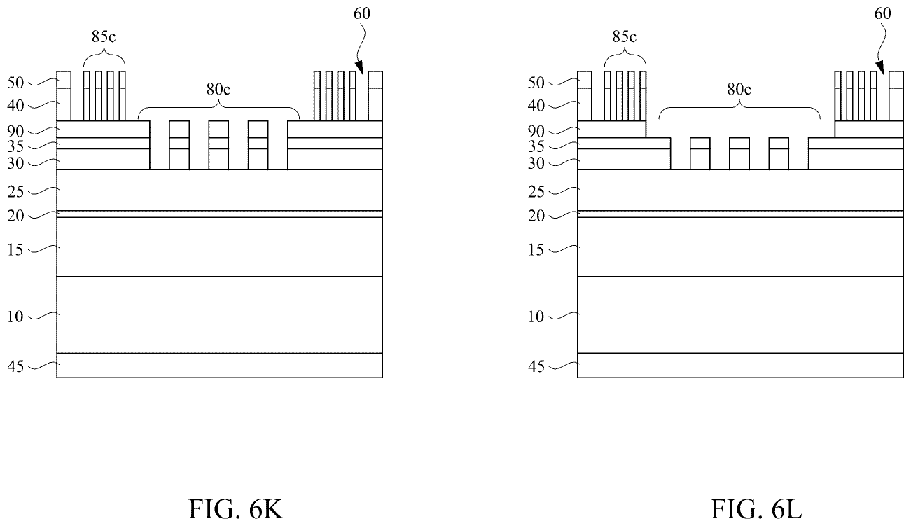

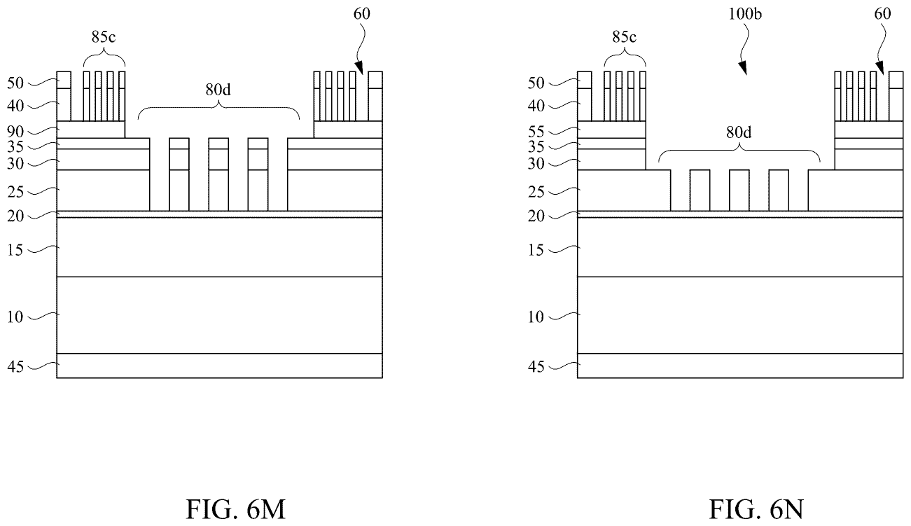

FIGS. 6A-6N schematically illustrate a method of manufacturing a photomask according to embodiments of the present disclosure. Materials, configurations, processes and/or dimensions as explained with respect to the foregoing embodiments may be employed in the following embodiments and detailed description thereof may be omitted. In the illustrated embodiments of FIGS. 6A-6N, the photomask includes two border layers 40, 50 and three hard mask layers 30, 35, 90 while in other embodiments, the photomask includes one or more than two border layers and one or more than three hard mask layers. Although a buffer layer is not shown in FIGS. 6A-6N, in other embodiments, the operations illustrated in FIGS. 6A-6N are performed on photomask blanks including a buffer layer.

A photomask blank is provided having at least one hard mask layer 30, 35 and at least one border layer 40, 50 disposed thereon according to any of the embodiments disclosed herein, as shown in FIG. 6A. In an embodiment, the photomask blank includes an absorber layer 25 made of CrN, with a first hard mask layer 30 made of TaBN, a second hard mask layer 35 made of TaBO, a third hard mask layer 90 made of CrON, a first border layer 40 made of Pt, and a second border layer 50 made of CrN disposed thereon, although the structure is not limited to these materials. An alignment mark 60 is formed in a peripheral region of the border layer 40, 50 in some embodiments, as shown in FIG. 6B. The alignment 60 is configured to align the photomask in subsequent processing operations. The alignment mark 60 is formed using suitable photolithographic and etching operations in some embodiments. The alignment mark may be formed around the periphery of the structure, or may be formed on one or more sides of the structure. In some embodiments, the alignment mark 60 is formed in the first and second border layers 40, 50 exposing a portion of the third hard mask layer 90.

A first photoresist layer 65 is formed over the structure of FIG. 6B, and the photoresist layer 65 is subsequently selectively exposed to actinic radiation and developed to form an opening 70a exposing a portion of the second border layer 50 and a pattern 85a including a plurality of alternating projections and recesses surrounding the opening 70a, as shown in FIG. 6C. In some embodiments, the photoresist layer 65 undergoes a post-exposure bake before the development operation. In some embodiments, the photoresist layer 65 is made of a chemically amplified resist or an organometallic resist, and the actinic radiation is deep ultraviolet radiation, extreme ultraviolet radiation, or an electron beam.

Using the photoresist layer 65 as a mask, portions of the second border layer are removed by a suitable etching operation, thereby exposing the first border layer 40 through extended opening 70b and the photoresist pattern 85a, as shown in FIG. 6D. Then, the first photoresist layer is removed by a suitable photoresist removal operation, such as a photoresist stripping or a plasma ashing operation, as shown in FIG. 6E.

In FIG. 6F, the exposed portions of the first border layer are then removed by a suitable etching operation, thereby exposing portions of the third hard mask layer 90 through the extended opening 70c and the extended photoresist pattern 85b. A second photoresist layer 75 is subsequently formed over the structure of FIG. 6F, as shown in FIG. 5G. The second photoresist layer 75 may be formed of the same material as the first photoresist layer 65 or may be formed of a different suitable photoresist.

The second photoresist layer 75 is subsequently selectively exposed to actinic radiation and developed to form a second pattern 80a exposing a portion of the uppermost hard mask layer. In some embodiments, the second photoresist layer 75 undergoes a post-exposure bake before the development operation. In this embodiment, portions of the third hard mask layer 90 are exposed by the second pattern 80a, as shown in FIG. 6H.

Using the second pattern 80a as a mask, the third hard mask layer 90 is etched to form a pattern 80b in the third hard mask layer 90 using a suitable etchant, as shown in FIG. 6I. In some embodiments, the etching operation is a dry etching operation. In some embodiments, the etching is anisotropic etching. The pattern 80b in the third hard mask layer 90 is an extension of the second pattern 80a in the second photoresist layer 75. The remaining photoresist layer is subsequently removed by a suitable photoresist removal operation, such as a photoresist stripping or a plasma ashing operation, as shown in FIG. 6J.

Then, using suitable etchants selective to the second hard mask layer 35 and first hard mask layer 30, the third pattern 80b in the third hard mask layer 90 is extended into the second and third hard mask layers 35, 30 forming a pattern 80c in the second and first hard mask layers 35, 30, as shown in FIG. 6K. The etching operation is a dry anisotropic etch in some embodiments. Then, a remaining portion of the third hard mask layer 90 in the opening 70c is removed using a suitable etchant selective to the third hard mask layer, as shown in FIG. 6L. In some embodiments, a portion of the second border layer 50 is removed while etching the third hard mask layer 90.

Using suitable etchants selective to the absorber layer 25, a pattern 80d is formed in the absorber layer 25, as shown in FIG. 6M. The pattern 80d in the absorber layer 25 corresponds to the pattern 80c formed in the first and second hard mask layers 30, 35. A patterned photomask 100b is formed in FIG. 6N by removing the portions of the first and second hard mask layers 30, 35 remaining in the opening 70c. The patterned border layers 40, 50 extend above and surround the absorber layer pattern 80d. The first and second hard mask layers 30, 35 are removed using suitable etchants selective to the first and second hard mask layers. In some embodiments, the etchant is a dry anisotropic etch.

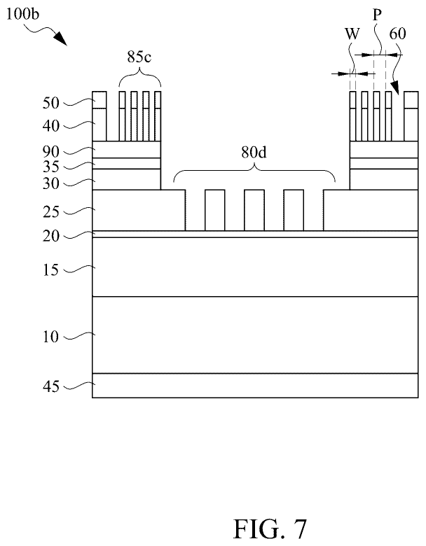

FIG. 7 illustrates a photomask 100b manufactured according to the embodiments disclosed with reference to FIGS. 6A-6N herein. When the width W of the border layer pattern 85c feature or the pitch P of the border pattern 85c is small enough in some embodiments, the destructive interference is increased thereby reducing the amount of reflected light. In some embodiments, the width of the border layer projections in the border layer pattern 85c is equal to or less than about 25 nm. In some embodiments, the pitch of the border layer pattern 85c features is equal to or less than about 50 nm.

In some embodiments, the border pattern 85c is a different pattern than alternating trenches and projections. For example, in some embodiments, the border pattern 85c is made up of a chessboard-like holes 85d having a width of about 5 nm to about 39 nm and a pitch of about 10 nm to about 40 nm, as shown in FIG. 8A. In other embodiments, the border pattern is made up of a series of staggered holes 85d, as shown in FIG. 8B. The holes 85d may have a width of about 5 nm to about 40 nm. In some embodiments, the border pattern 85c of projections and trenches are oriented at an angle to the borders of the photomask or the main pattern, as shown in FIG. 8C. In other embodiments, the border pattern 85c of projections and trenches are curvilinear, as shown in FIG. 8D. In some embodiments, the border pattern 85c is made up polygon-shaped holes 85d, which may be regularly arranged, as shown in FIG. 8E, or staggered. In some embodiments, the pitch of the border pattern 85c is not fixed, and can vary between adjacent projections, as shown in FIG. 8F. In other embodiments, the border pattern 85c the widths of the projections and trenches is not fixed, and can vary between adjacent projections and trenches, as shown in FIG. 8G. The border pattern 85c may be made up of combination of different patterns, as shown in FIG. 8H. In some embodiments, the border pattern 85c overlaps the main pattern 80d or is attached to the main pattern 80d, as shown in FIGS. 8I and 8J, respectively. The border pattern that overlaps or is attached to the main pattern 80d may include a series or array of sub-resolution assist features (SRAF) 85e. The border pattern designs covered by the scope of this disclosure are not limited to the disclosed embodiments. When the width of the projections or holes or the pitch of the border pattern is small enough, destructive interference can be increased to reduce the reflected light.

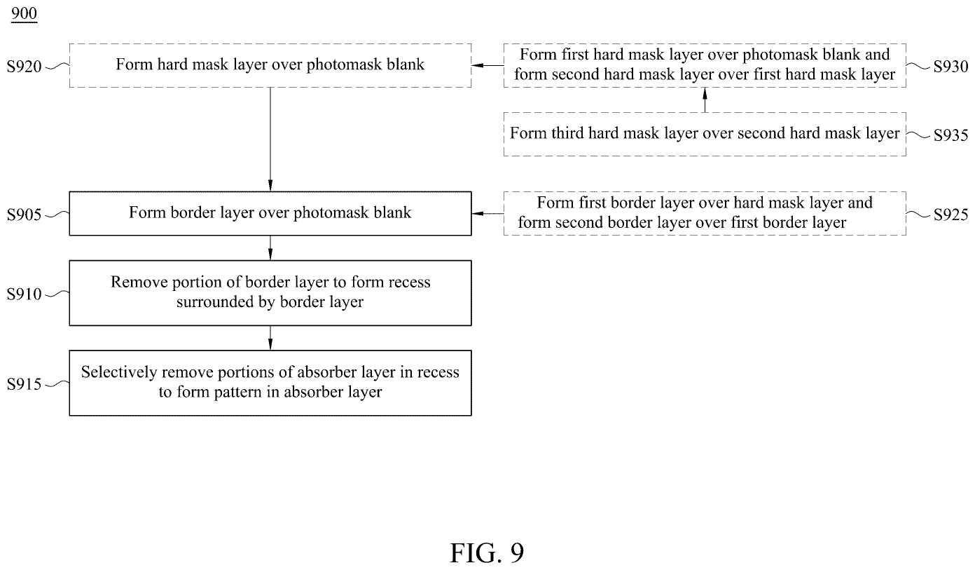

FIG. 9 shows a flowchart of a method 900 of manufacturing a photomask according to an embodiment of the disclosure. Materials, configurations, processes and/or dimensions as explained with respect to the foregoing embodiments may be employed in the following embodiments and detailed description thereof may be omitted. The method 900 includes an operation S905 of forming a border layer 40, 50 over a photomask blank 5a. The photomask blank 5a includes: a substrate 10, a reflective multilayer 15 disposed over the substrate 10, and an absorber layer 25 disposed over the reflective multilayer 15. A portion of the border layer 40, 50 is removed in operation S910 to form a recess 70a surrounded by the border layer 40, 50, and portions of the absorber layer 25 are selectively removed in operation S915 in the recess to form a pattern 80d in the absorber layer 25. The border layer 40, 50 has a refractive index ranging from about 0.87 to about 1 and an extinction coefficient greater than or equal to about 0.02 in some embodiments. In some embodiments, the border layer 40, 50 has an extinction coefficient ranging from 0.02 to 0.1. In some embodiments, the method 900 includes an operation S920 of forming a hard mask layer 30, 35, 90 over the photomask blank 5a before forming the border layer 40, 50 over the photomask blank. In an embodiment, the forming the border layer includes an operation S925 of forming a first border layer 40 over the hard mask layer 30, 35, 90, and forming a second border 50 layer over the first border layer 40, wherein the first border layer and the second border layer are made of different materials. In some embodiments, forming the hard mask layer further includes an operation S930 of forming a first hard mask layer 30 over the photomask blank 5b, and forming a second hard mask layer 35 over the first hard mask layer 30, wherein the first hard mask layer 30 and the second hard mask layer 35 are made of different materials. In an embodiment, the method 900 includes an operation forming a third hard mask layer 90 over the second hard mask layer 35, wherein the third hard mask layer is made of a different material than the second hard mask layer.

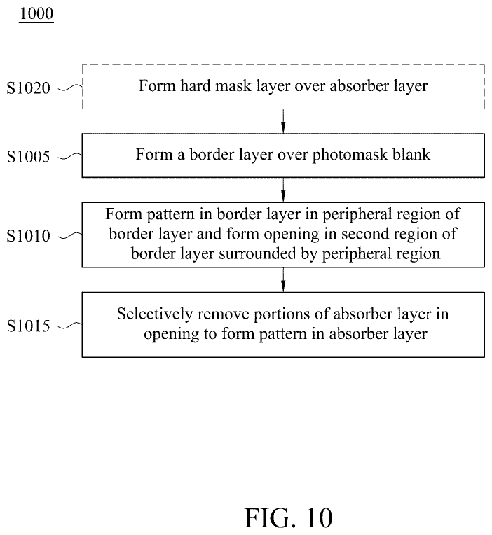

FIG. 10 shows a flowchart 1000 of a method of manufacturing a photomask 100b according to some embodiments of the disclosure. Materials, configurations, processes and/or dimensions as explained with respect to the foregoing embodiments may be employed in the following embodiments and detailed description thereof may be omitted. The method 1000 includes an operation of S1005 of forming a border layer 40, 50 over a photomask blank 5a. The photomask blank 5a includes a substrate 10, a reflective multilayer 15 disposed over the substrate, and an absorber layer 25 disposed over the reflective multilayer. In operation S1010, a pattern 85c is formed in a peripheral region of the border layer 40, 50 and an opening 70c is formed in a second region of the border layer surrounded by the peripheral region, wherein the pattern in the border layer includes at least two spaced apart trenches and two spaced apart projections in each side of border layer in a cross sectional view. Portions of the absorber layer in the opening are selectively removed in operation S1015 to form a pattern in the absorber layer. The border layer 40, 50 includes at least one selected from the group consisting of Rh, Pd, Ir, Pt, Co, Ni, Te, Cr, W, Hf, Ta, PtRu, PtIr, PtRh, PtPd, PtNi, PtCo, PtTa, PtCr, PtTi, IrTa, IrCr, IrW, IrTe, IrNi, IrCo, CrN, NiCo, RhCo, RhNi, RhCr, RhW, and RhTa. In some embodiments, the border layer 40, 50 is doped with at least one of nitrogen, boron, oxygen, or oxynitride. In some embodiments, the method includes an operation of forming a hard mask layer 30, 35, 90 over the absorber layer 25 before forming the border layer 40, 50.

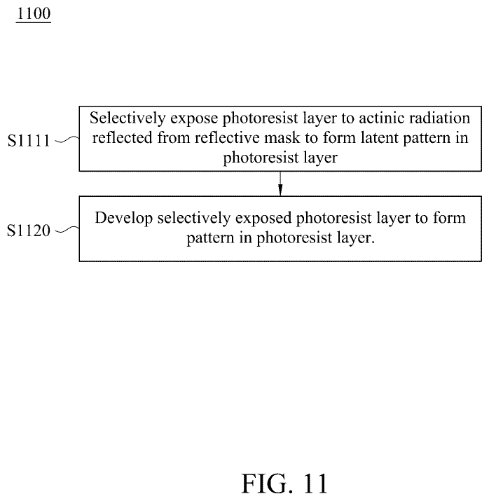

FIG. 11 shows a flowchart of a method 1100 of manufacturing a semiconductor device according to some embodiments of the disclosure. Materials, configurations, processes and/or dimensions as explained with respect to the foregoing embodiments may be employed in the following embodiments and detailed description thereof may be omitted. The method 1100 of manufacturing a semiconductor device includes an operation S1110 selectively exposing a photoresist layer PR to actinic radiation reflected from a reflective mask (100a, 100b) to form a latent pattern in the photoresist layer PR. The reflective mask 100a, 100b can be any of the masks disclosed herein including a substrate 10, a reflective multilayer 15 disposed over the substrate, an absorber layer 25 including a pattern 80d in the absorber layer disposed over the reflective multilayer, and a border layer 40, 50 surrounding the pattern in the absorber layer in plan view. The border layer has a refractive index ranging from 0.87 to 1 and an extinction coefficient greater than or equal to 0.02. The selectively exposed photoresist layer is developed in operation S1120 to form a pattern in the photoresist layer.

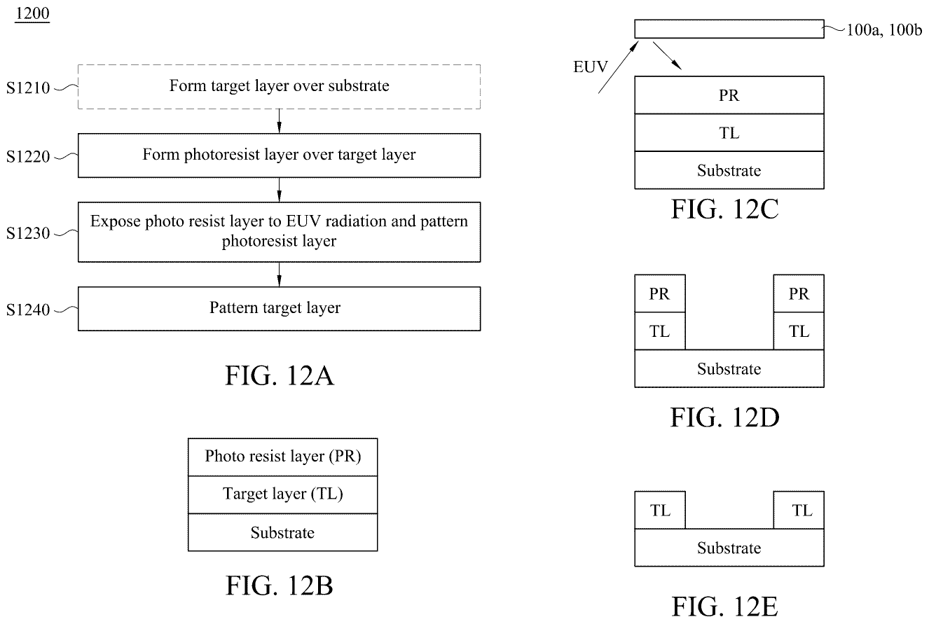

FIG. 12A shows a flowchart of a method manufacturing a semiconductor device, and FIGS. 12B, 12C, 12D and 12E show a sequential manufacturing operation of a method of making a semiconductor device in accordance with embodiments of present disclosure.

Materials, configurations, processes and/or dimensions as explained with respect to the foregoing embodiments may be employed in the following embodiments and detailed description thereof may be omitted.

A semiconductor substrate or other suitable substrate to be patterned to form an integrated circuit thereon is provided. In some embodiments, the semiconductor substrate includes silicon. Alternatively or additionally, the semiconductor substrate includes germanium, silicon germanium or other suitable semiconductor material, such as a Group III-V semiconductor material. In operation S1210 of FIG. 12A, a target layer to be patterned is formed over the semiconductor substrate. In some embodiments, the target layer is the semiconductor substrate. In some embodiments, the target layer includes a conductive layer, such as a metallic layer or a polysilicon layer; a dielectric layer, such as silicon oxide, silicon nitride, SiON, SiOC, SiOCN, SiCN, hafnium oxide, or aluminum oxide; or a semiconductor layer, such as an epitaxially formed semiconductor layer. In some embodiments, the target layer is formed over an underlying structure, such as isolation structures, transistors, or wirings. In operation S1220, a photoresist layer PR is formed over the target layer TL, as shown in FIG. 12B. The photoresist layer PR is sensitive to the radiation from the exposing source during a subsequent photolithography exposing process. In the present embodiment, the photoresist layer PR is sensitive to EUV light used in the photolithography exposing process. The photoresist layer PR may be formed over the target layer by spin-on coating or other suitable techniques. The coated photo resist layer may be further baked to drive out solvent in the photo resist layer. In operation S1230, the photoresist layer is patterned using an EUV reflective mask 100a, 100b as described in any of the embodiments herein, as shown in FIG. 12C. The patterning of the photoresist layer includes performing a photolithography exposing process by an EUV exposing system using the EUV reflective mask 100a, 100b. During the exposing process, the integrated circuit (IC) design pattern defined on the EUV reflective mask 100a, 100b is imaged to the photoresist layer PR to form a latent pattern thereon. The patterning of the photoresist layer PR further includes developing the exposed photoresist layer to form a patterned photoresist layer having one or more openings. In one embodiment where the photoresist layer is a positive tone photoresist layer, the exposed portions of the photoresist layer PR are removed during the developing process. In another embodiment where the photoresist layer PR is a negative tone photoresist, the unexposed portions of the photoresist layer PR are removed during the developing. The patterning of the photoresist layer may further include other process steps, such as various baking steps at different stages. For example, a post-exposure-baking (PEB) process may be implemented after the photolithography exposing process and before the developing process.

In operation S1240, the target layer is patterned using the patterned photoresist layer as an etching mask, as shown in FIG. 12D. In some embodiments, patterning the target layer includes applying an etching process to the target layer using the patterned photoresist layer as an etch mask. The portions of the target layer exposed within the openings of the patterned photoresist layer are etched while the remaining portions are protected from etching. Further, the patterned photoresist layer may be removed by wet stripping or plasma ashing, as shown in FIG. 12E.

Embodiments of the present disclosure provide techniques to prevent or suppress the neighboring die effect, thereby increasing semiconductor device yield. In some embodiments, the border layers surrounding the mask pattern regions according embodiments of the present disclosure mitigate the neighboring die effect as effectively as a black border without the issues encountered in forming a black border such as flatness change and defects, using multiple exposure masks, and two layer stitching issues. The border layer mitigates EUV radiation reflection from the non-patterned areas (border areas or peripheral areas) of the EUV mask onto a substrate being patterned. In some embodiments including a patterned border layer, when the width W of the border layer pattern feature or the pitch of the border pattern 85c is sufficiently small, the destructive interference is increased thereby reducing the amount of reflected light.

In some embodiments, a 16.5 nm thick PtRu border layer 40 is disposed over a third hard mask layer 90 made of CrON, a second hard mask 35 made of TaBO, and a first hard mask layer 30 made of TaBN. In another embodiment, a 16.5 nm thick PtRu border layer 40 is disposed over a third hard mask layer 90 made of CrON, a second hard mask layer 35 made of TaBO, and a first hard mask layer 30 made of TaBN, and the PtRu border layer 40 is patterned having a pitch of 22 nm.

In other embodiments, the first border layer 40 and the second border layer 50 have different thicknesses. In these embodiments, a CrN first border layer 40 and a second TaBN border layer 50 are disposed over a TaBN first hard mask layer 30, a TaBO second hard mask layer 35, and a CrON third hard mask layer 90. In one embodiment, the first border layer 40 has a thickness of about 18 nm and the second border layer 50 has a thickness of about 19 nm. In another embodiment, the first border layer 40 has a thickness of about 19 nm and the second border layer 50 has a thickness of about 18 nm. In another embodiment, the first border layer 40 has a thickness of about 17 nm and the second border layer 50 has a thickness of about 20 nm. In another embodiment, the first border layer 40 has a thickness of about 17 nm and the second border layer 50 has a thickness of about 13 nm.

In another embodiment, the first border layer 40 is made of Pt and it has a thickness of about 20 nm and the second border layer 50 is made of TaBN and has a thickness of about 4 nm. In another embodiment, the first border layer 40 is made of Pt and has a thickness of about 13 nm and the second border layer is made of TaBN and has a thickness of about 11 nm. In another embodiment, the first border layer 40 is made of Pt and has a thickness of about 12 nm and the second border layer 50 is made of TaBN and has a thickness of about 19 nm.

In another embodiment, the first border layer 40 is made of CrN and has a thickness of about 4 nm and the second border layer 50 is made of Pt and has a thickness of about 20 nm. In another embodiment, the first border layer 40 is made of TaBN and has a thickness of about 19 nm and the second border layer 50 is made of CrN and has a thickness of about 18 nm. In another embodiment, the first border layer 40 is made of CrN and has a thickness of about 11 nm and the second border layer 50 is made of PtRu and has a thickness of about 20 nm.

It will be understood that not all advantages have been necessarily discussed herein, no particular advantage is required for all embodiments or examples, and other embodiments or examples may offer different advantages.

According to an embodiment of the disclosure, a method of manufacturing a photomask includes forming a border layer over a photomask blank. The photomask blank includes: a substrate, a reflective multilayer disposed over the substrate, and an absorber layer disposed over the reflective multilayer. A portion of the border layer is removed to form a recess surrounded by the border layer, and portions of the absorber layer are selectively removed in the recess to form a pattern in the absorber layer. The border layer has a refractive index ranging from 0.87 to 1 and an extinction coefficient greater than or equal to 0.02. In an embodiment, the border layer has an extinction coefficient ranging from 0.02 to 0.1. In an embodiment, the method includes forming a hard mask layer over the photomask blank before forming the border layer over the photomask blank. In an embodiment, during the removing a portion of border layer, a portion of the hard mask layer is exposed. In an embodiment, the forming the border layer includes: forming a first border layer over the hard mask layer, and forming a second border layer over the first border layer, wherein the first border layer and the second border layer are made of different materials. In an embodiment, forming the hard mask layer further includes: forming a first hard mask layer over the photomask blank, and forming a second hard mask layer over the first hard mask layer, wherein the first hard mask layer and the second hard mask layer are made of different materials. In an embodiment, the method includes forming a third hard mask layer over the second hard mask layer, wherein the third hard mask layer is made of a different material than the second hard mask layer. In an embodiment, the photomask blank includes a capping layer disposed between the reflective multilayer and the absorber layer. In an embodiment, during the selectively removing portions of the absorber layer, portions of the capping layer are exposed.

In another embodiment of the disclosure, a method of manufacturing a photomask includes forming a border layer over a photomask blank. The photomask blank includes: a substrate, a reflective multilayer disposed over the substrate, and an absorber layer disposed over the reflective multilayer. A pattern is formed in a peripheral region of the border layer and an opening is formed in a second region of the border layer surrounded by the peripheral region, wherein the pattern in the border layer includes at least two spaced apart trenches and two spaced apart projections in each side of border layer in a cross sectional view. Portions of the absorber layer in the opening are selectively removed to form a pattern in the absorber layer. The border layer includes at least one selected from the group consisting of Rh, Pd, Ir, Pt, Co, Ni, Te, Cr, W, Hf, Ta, PtRu, PtIr, PtRh, PtPd, PtNi, PtCo, PtTa, PtCr, PtTi, IrTa, IrCr, IrW, IrTe, IrNi, IrCo, CrN, NiCo, RhCo, RhNi, RhCr, RhW, and RhTa. In an embodiment, the border layer is doped with at least one of nitrogen, boron, oxygen, or oxynitride. In an embodiment, the absorber layer includes at least one of PtRu, IrRu, OsRu, HfRu, RhRu, TaRu, PtRuN, IrRuN, OsRuN, HfRuN, RhRuN, RuCr, IrTaON, CrN, TaBN, TaN, RuW, RuN, and TaRuN. In an embodiment, the method includes forming a hard mask layer over the absorber layer before forming the border layer. In an embodiment, the pattern in the border layer exposes the hard mask layer. In an embodiment, the projections in the pattern in the border layer have a width of less than or equal to 25 nm in cross sectional view.

In another embodiment of the disclosure, a method of manufacturing a semiconductor device includes selectively exposing a photoresist layer to actinic radiation reflected from a reflective mask to form a latent pattern in the photoresist layer. The reflective mask includes: a substrate, a reflective multilayer disposed over the substrate, an absorber layer including a pattern in the absorber layer disposed over the reflective multilayer, and a border layer surrounding the pattern in the absorber layer in plan view. The border layer has a refractive index ranging from 0.87 to 1 and an extinction coefficient greater than or equal to 0.02. The selectively exposed photoresist layer is developed to form a pattern in the photoresist layer. In an embodiment, the actinic radiation is extreme ultraviolet radiation. In an embodiment, the border layer includes a pattern having at least two spaced apart trenches and two spaced apart projections in each side of border layer in a cross sectional view. In an embodiment, the border layer includes at least one selected from the group consisting of Rh, Pd, Ir, Pt, Co, Ni, Te, Cr, W, Hf, Ta, PtRu, PtIr, PtRh, PtPd, PtNi, PtCo, PtTa, PtCr, PtTi, IrTa, IrCr, IrW, IrTe, IrNi, IrCo, CrN, NiCo, RhCo, RhNi, RhCr, RhW, and RhTa. In an embodiment, the border layer includes at least a first border layer disposed over the absorber layer and a second border layer formed of a different material than the first border layer disposed over the first border layer.

In another embodiment of the disclosure, a photomask includes a substrate and a reflective multilayer disposed over the substrate. An absorber layer including a pattern in the absorber layer is disposed over the reflective multilayer, and a border layer surrounds the pattern in the absorber layer in plan view. The border layer has a refractive index ranging from 0.87 to 1 and an extinction coefficient greater than or equal to 0.02. In an embodiment, the border layer has an extinction coefficient ranging from 0.02 to 0.1. In an embodiment, an uppermost surface of the border layer is located at a greater distance from an uppermost surface of the substrate than an uppermost surface of the absorber layer. In an embodiment, the photomask includes a hard mask layer disposed between the absorber layer and the border layer. In an embodiment, the border layer includes a first border layer disposed over the hard mask layer and a second border layer disposed over the first border layer, wherein the first border layer and the second border layer are made of different materials. In an embodiment, the hard mask layer includes a first hard mask layer disposed over the absorber layer, and a second hard mask layer disposed over the first hard mask layer, wherein the first hard mask layer and the second hard mask layer are made of different materials. In an embodiment, the photomask includes a third hard mask layer disposed over the second hard mask layer, wherein the third hard mask layer is made of a different material than the second hard mask layer. In an embodiment, the photomask includes a capping layer disposed between the reflective multilayer and the absorber layer, wherein the capping layer is made of a different material than the reflective multilayer and the absorber layer. In an embodiment, the photomask includes a buffer layer disposed between the substrate and the reflective multilayer, wherein the buffer layer is made of a different material than the substrate and the reflective multilayer.

In another embodiment of the disclosure, a photomask includes a substrate and a reflective multilayer disposed over the substrate. A patterned absorber layer including a first pattern is disposed over the reflective multilayer, and a patterned border layer having a second pattern surrounds the first pattern in plan view. The second pattern includes at least two spaced apart trenches and two spaced apart projections in each side of border layer in a cross sectional view. The projections in the pattern in the border layer have a width of less than or equal to 25 nm in cross sectional view. In an embodiment, an uppermost surface of the border layer is located at a greater distance from an uppermost surface of the substrate than an uppermost surface of the absorber layer. In an embodiment, the photomask includes a hard mask layer disposed between the absorber layer and the border layer, wherein the hard mask layer is made of a different material than the absorber layer and the border layer. In an embodiment, the second pattern exposes the hard mask layer. In an embodiment, the hard mask layer includes a first hard mask layer disposed over the absorber layer and a second hard mask layer disposed over the first hard mask layer, wherein the first hard mask layer and the second hard mask layer are made of different materials. In an embodiment, the border layer includes a first border layer disposed over the hard mask layer and a second border layer disposed over the first border layer, wherein the first border layer and the second border layer are made of different materials.

In another embodiment of the disclosure a photomask includes a substrate and a reflective multilayer disposed over the substrate. A patterned absorber layer including a first pattern is disposed over the reflective multilayer, and a border layer surrounds the first pattern in plan view. The border layer includes at least one selected from the group consisting of Rh, Pd, Ir, Pt, Co, Ni, Te, Cr, W, Hf, Ta, PtRu, PtIr, PtRh, PtPd, PtNi, PtCo, PtTa, PtCr, PtTi, IrTa, IrCr, IrW, IrTe, IrNi, IrCo, CrN, NiCo, RhCo, RhNi, RhCr, RhW, and RhTa. The absorber layer includes at least one of PtRu, IrRu, OsRu, HfRu, RhRu, TaRu, PtRuN, IrRuN, OsRuN, HfRuN, RhRuN, RuCr, IrTaON, CrN, TaBN, TaN, RuW, RuN, and TaRuN. In an embodiment, the photomask includes a hard mask layer disposed between the absorber layer and the border layer, wherein the hard mask layer is made of a different material than the absorber layer and the border layer. In an embodiment, the hard mask layer includes a first hard mask layer disposed over the absorber layer and a second hard mask layer disposed over the first hard mask layer, wherein the first hard mask layer and the second hard mask layer are made of different materials. In an embodiment, the border layer includes a first border layer disposed over the hard mask layer and a second border layer disposed over the first border layer, wherein the first border layer and the second border layer are made of different materials. In an embodiment, the photomask includes a capping layer disposed between the reflective multilayer and the absorber layer, wherein the capping layer is made of a different material than the reflective multilayer and the absorber layer.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a photomask, comprising:
forming a border layer over a photomask blank,
wherein the photomask blank includes:
a substrate;
a reflective multilayer disposed over the substrate; and
an absorber layer disposed over the reflective multilayer;
removing a portion of the border layer to form a recess surrounded by the border layer; and
selectively removing portions of the absorber layer in the recess to form a pattern in the absorber layer,
wherein the border layer has a refractive index ranging from 0.87 to 1 and an extinction coefficient greater than or equal to 0.02.

2. The method according to claim 1, wherein the border layer has an extinction coefficient ranging from 0.02 to 0.1.

3. The method according to claim 1, further comprising forming a hard mask layer over the photomask blank before forming the border layer over the photomask blank.

4. The method according to claim 3, wherein during the removing a portion of border layer, a portion of the hard mask layer is exposed.

5. The method according to claim 3, wherein forming the border layer further comprises:
forming a first border layer over the hard mask layer; and
forming a second border layer over the first border layer,
wherein the first border layer and the second border layer are made of different materials.

6. The method according to claim 3, wherein forming the hard mask layer further comprises:
forming a first hard mask layer over the photomask blank; and
forming a second hard mask layer over the first hard mask layer,
wherein the first hard mask layer and the second hard mask layer are made of different materials.

7. The method according to claim 6, further comprising forming a third hard mask layer over the second hard mask layer, wherein the third hard mask layer is made of a different material than the second hard mask layer.

8. The method according to claim 1, wherein the photomask blank includes a capping layer disposed between the reflective multilayer and the absorber layer.

9. The method according to claim 8, wherein during the selectively removing portions of the absorber layer, portions of the capping layer are exposed.

10. A method of manufacturing a photomask, comprising:
forming a border layer over a photomask blank,
wherein the photomask blank includes:
a substrate;
a reflective multilayer disposed over the substrate; and
an absorber layer disposed over the reflective multilayer;
forming a pattern in a peripheral region of the border layer and forming an opening in a second region of the border layer surrounded by the peripheral region,
wherein the pattern in the border layer includes at least two spaced apart trenches and two spaced apart projections in each side of border layer in a cross sectional view; and
selectively removing portions of the absorber layer in the opening to form a pattern in the absorber layer,
wherein the border layer includes at least one selected from the group consisting of Rh, Pd, Ir, Pt, Co, Ni, Te, Cr, W, Hf, Ta, PtRu, PtIr, PtRh, PtPd, PtNi, PtCo, PtTa, PtCr, PtTi, IrTa, IrCr, IrW, IrTe, IrNi, IrCo, CrN, NiCo, RhCo, RhNi, RhCr, RhW, and RhTa.

11. The method according to claim 10, wherein the border layer is doped with at least one of nitrogen, boron, oxygen, or oxynitride.

12. The method according to claim 10, wherein the absorber layer includes at least one of PtRu, IrRu, OsRu, HfRu, RhRu, TaRu, PtRuN, IrRuN, OsRuN, HfRuN, RhRuN, RuCr, IrTaON, CrN, TaBN, TaN, RuW, RuN, and TaRuN.

13. The method according to claim 10, further comprising forming a hard mask layer over the absorber layer before forming the border layer.

14. The method according to claim 13, wherein the pattern in the border layer exposes the hard mask layer.

15. The method according to claim 10, wherein the projections in the pattern in the border layer have a width of less than or equal to 25 nm in cross sectional view.

16. A photomask, comprising:
a substrate;
a reflective multilayer disposed over the substrate;
an absorber layer including a pattern in the absorber layer disposed over the reflective multilayer; and
a border layer surrounding the pattern in the absorber layer in plan view,
wherein the border layer has a refractive index ranging from 0.87 to 1 and an extinction coefficient greater than or equal to 0.02.

17. The photomask of claim 16, wherein the border layer has an extinction coefficient ranging from 0.02 to 0.1.

18. The photomask of claim 16, wherein an uppermost surface of the border layer is located at a greater distance from an uppermost surface of the substrate than an uppermost surface of the absorber layer.

19. The photomask of claim 16, further comprising a hard mask layer disposed between the absorber layer and the border layer.

20. The photomask of claim 19, wherein the border layer comprises:
a first border layer disposed over the hard mask layer; and
a second border layer disposed over the first border layer,
wherein the first border layer and the second border layer are made of different materials.
